(19) United States
(12) Patent Application Publication
(10) Pub. No.: US 2026/0005406 A1
(43) Pub. Date: Jan. 1, 2026

(54) BUSBAR MODULE

(71) Applicant: YAZAKI CORPORATION, Tokyo (JP)

(72) Inventors: Mariko Nakagawa, Makinohara-shi (JP); Tatsuya Oga, Makinohara-shi (JP); Katsunori Sato, Makinohara-shi (JP); Seigo Mochizuki, Fujieda-shi (JP)

(21) Appl. No.: 19/234,252

(22) Filed: Jun. 10, 2025

(30) Foreign Application Priority Data
Jun. 26, 2024 (JP) 2024-102586

(51) Int. Cl. H01M 50/507; H01M 50/519; H01M 50/569; H01M 50/583; H05K 1/18; H05K 3/28

(52) U.S. Cl. CPC H01M 50/507; H01M 50/519; H01M 50/569; H01M 50/583; H05K 1/189; H05K 3/284; H05K 2201/10181

(57) ABSTRACT

A busbar module includes: a flexible printed circuit board; a plurality of busbars connected to the flexible printed circuit board; a plurality of chip fuses connected to the busbar; and a potting agent covering the plurality of chip fuses, in which the plurality of chip fuses are mounted in one mounting region of the flexible printed circuit board, and the potting agent is disposed in the one mounting region and covers the plurality of chip fuses.

### CROSS-REFERENCE TO RELATED APPLICATION(S)

The present application claims priority to and incorporates by reference the entire contents of Japanese Patent Application No. 2024-102586 filed in Japan on Jun. 26, 2024.

### BACKGROUND OF THE INVENTION

### 1. Field of the Invention

The present invention relates to a busbar module.

### 2. Description of the Related Art

Hitherto, there is a busbar module on which a chip fuse is mounted. JP 2022-173 609 A discloses a busbar module including a plurality of busbars fixed to battery cells of a battery module, a plate-like circuit body having flexibility, and a case that houses the circuit body and the busbars. A chip fuse is mounted on the circuit body of JP 2022-173 609 A.

In a busbar module on which a chip fuse is mounted, it is desirable that manufacturing efficiency can be improved. The manufacturing efficiency is likely to deteriorate, for example, in a case where a sealing process is individually performed on a plurality of chip fuses.

### SUMMARY OF THE INVENTION

An object of the present invention is to provide a busbar module that enables improvement of manufacturing efficiency.

In order to achieve the above mentioned object, a busbar module according to one aspect of the present invention includes a flexible printed circuit board; a plurality of busbars connected to the flexible printed circuit board; a plurality of chip fuses connected to the busbar; and a potting agent covering the plurality of chip fuses, wherein the plurality of chip fuses are mounted in one mounting region of the flexible printed board, and the potting agent is disposed in the one mounting region and covers the plurality of chip fuses.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a plan view of a busbar module according to an embodiment;

FIG. 2 is a plan view of the busbar module according to the embodiment;

FIG. 3 is a view illustrating an application example of the busbar module according to the embodiment;

FIG. 4 is a plan view of a flexible printed circuit board according to the embodiment;

FIG. 5 is a cross-sectional view of the busbar module according to the embodiment;

FIG. 6 is a plan view of a case according to the embodiment; and

FIG. 7 is a plan view of another busbar module according to the embodiment.

### DETAILED DESCRIPTION OF THE PREFERRED EMBODIMENTS

Hereinafter, a busbar module according to an embodiment of the present invention will be described in detail with reference to the drawings. Note that the present invention is not limited by the embodiment. In addition, constituent elements in the following embodiment include those that can be easily assumed by those skilled in the art or those that are substantially the same.

### Embodiment

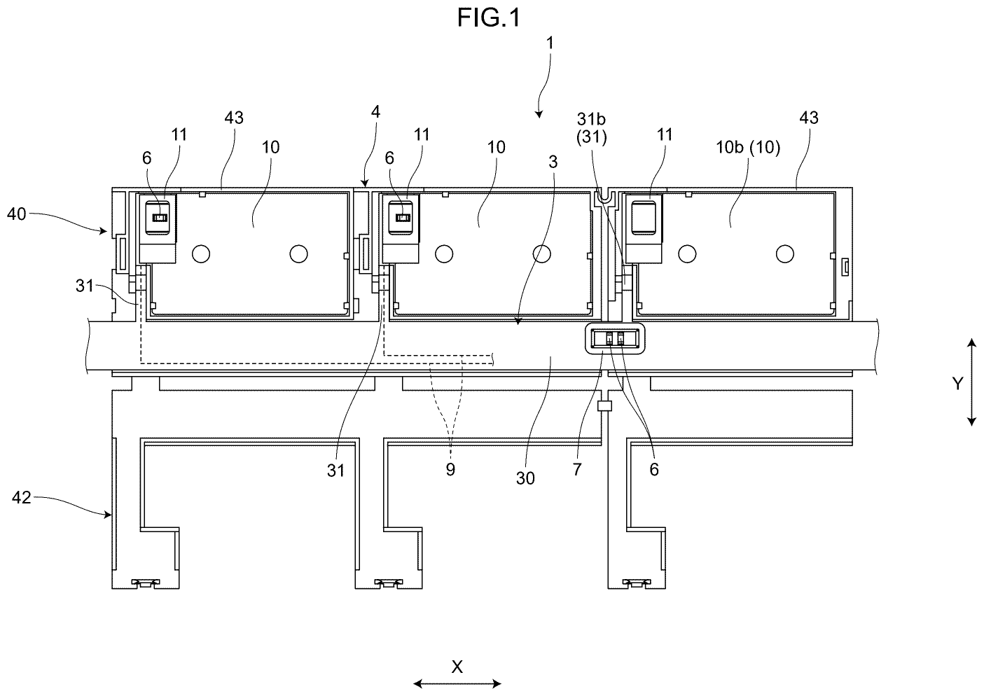

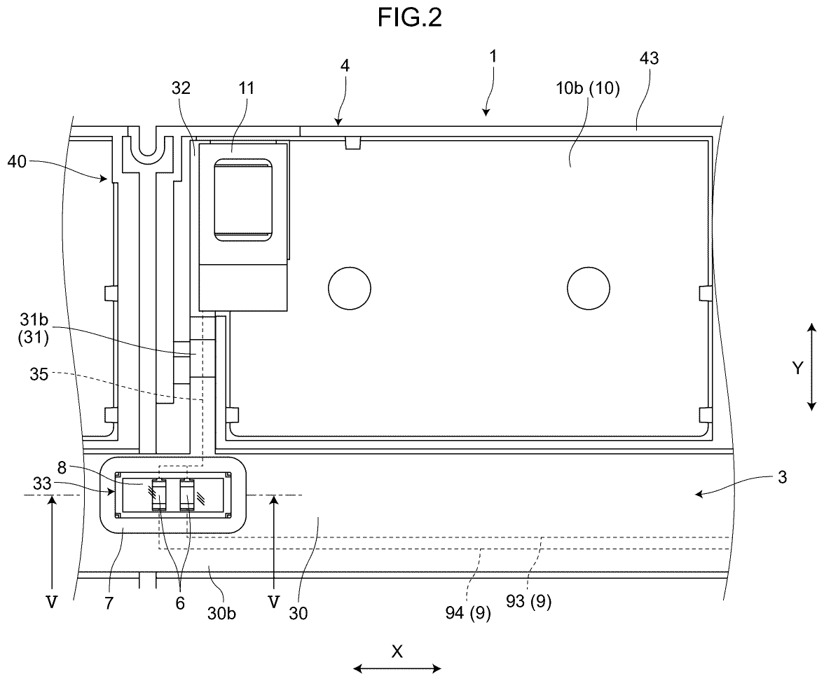

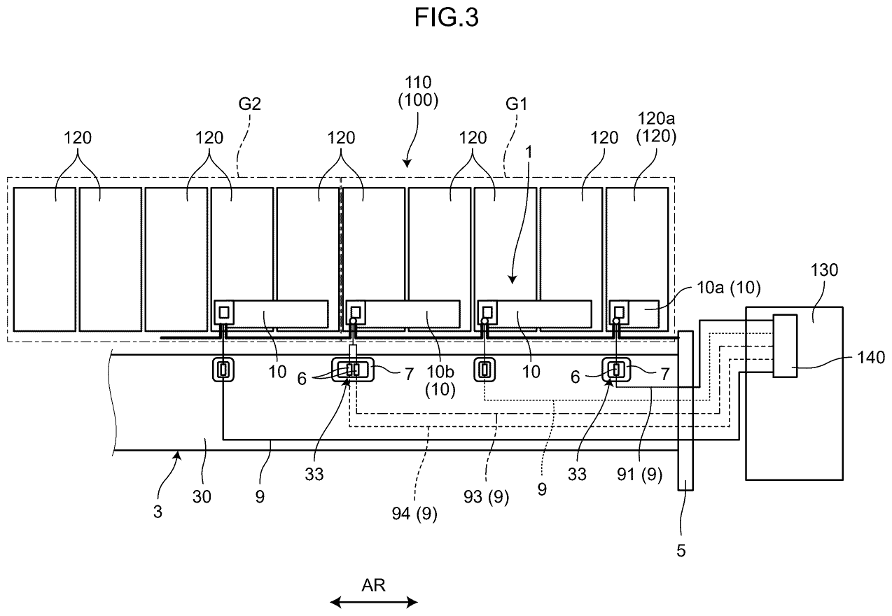

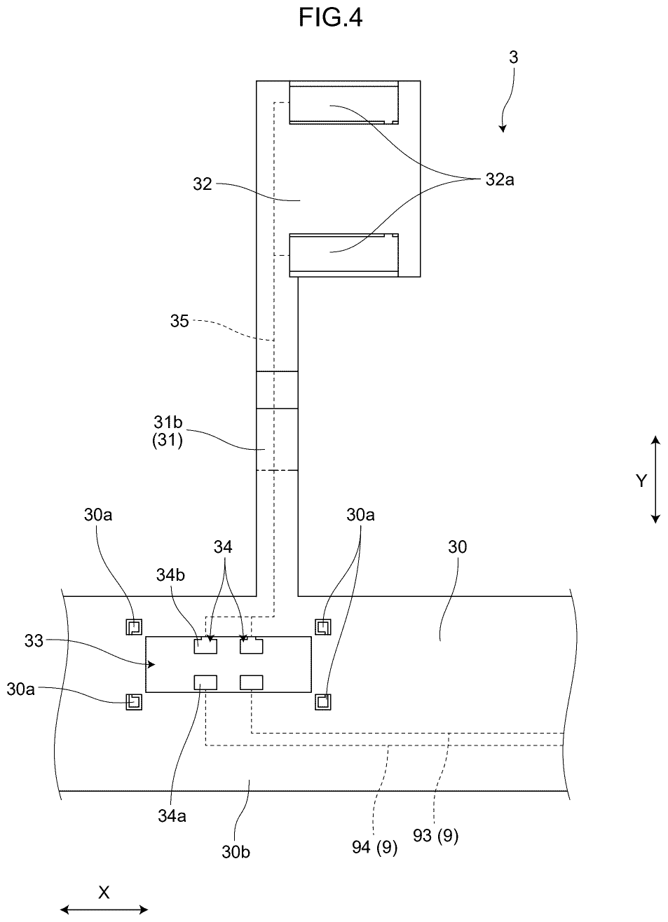

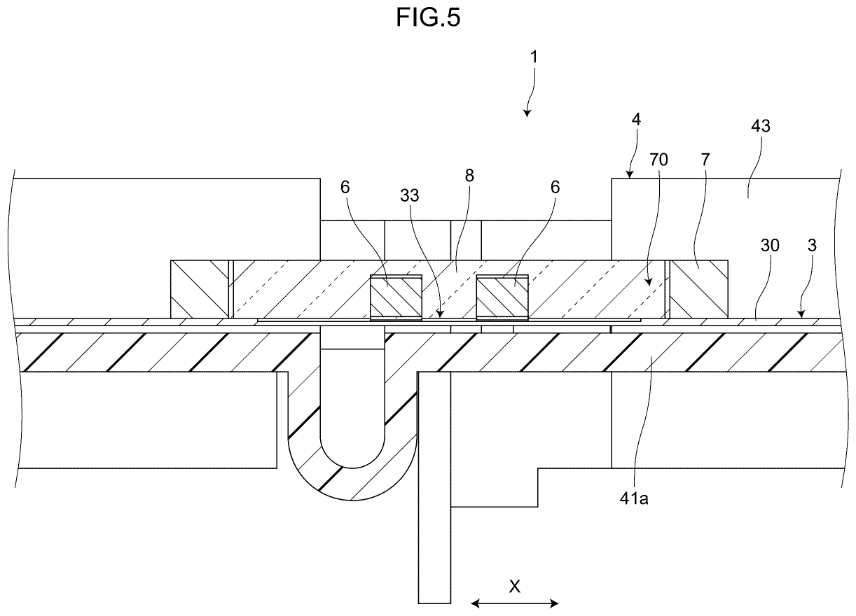

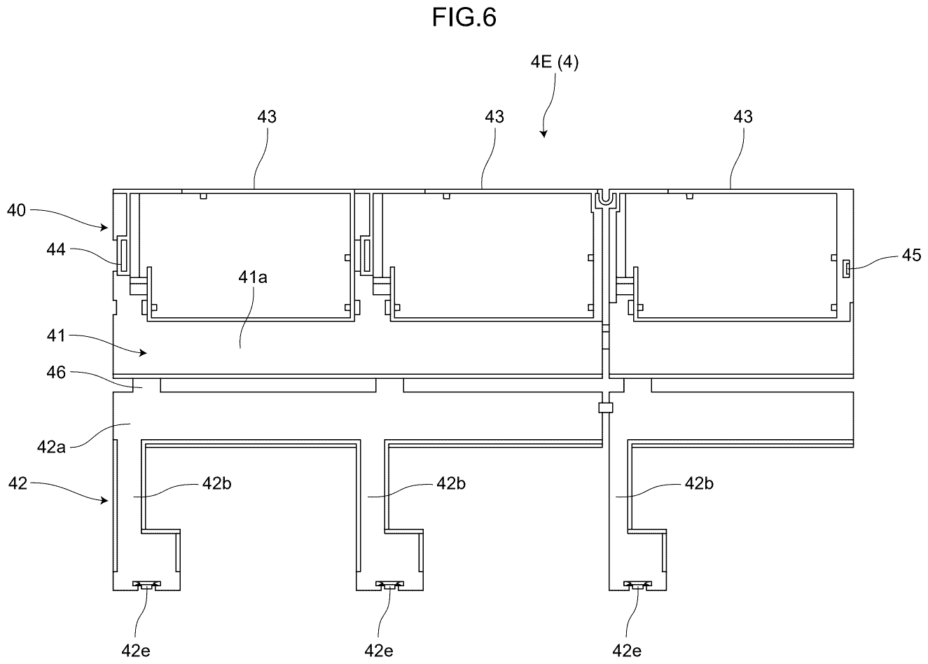

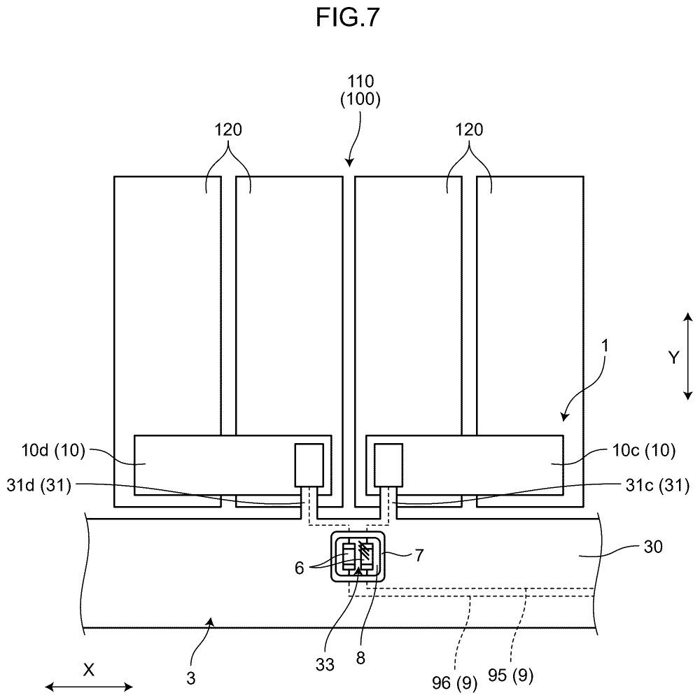

An embodiment will be described with reference to FIGS. 1 to 7. The present embodiment relates to a busbar module. FIGS. 1 and 2 are plan views of the busbar module according to the embodiment, FIG. 3 is a view illustrating an application example of the busbar module according to the embodiment, FIG. 4 is a plan view of a flexible printed circuit board according to the embodiment, FIG. 5 is a cross-sectional view of the busbar module according to the embodiment, FIG. 6 is a plan view of a case according to the embodiment, and FIG. 7 is a plan view of another busbar module according to the embodiment. FIG. 5 illustrates a cross section taken along line V-V of FIG. 2.

As illustrated in FIG. 1, a busbar module 1 according to the present embodiment includes a flexible printed circuit board 3, a case 4, a plurality of busbars 10, a plurality of chip fuses 6, a reinforcing plate 7, and a potting agent 8. For example, as illustrated in FIG. 3, the busbar module 1 is disposed in a battery module 110 of a battery pack 100. The battery module 110 includes a plurality of battery cells 120 arranged in an arrangement direction AR. The battery pack 100 is mounted as a power supply on a vehicle such as an electric vehicle or a hybrid electric vehicle, for example.

The busbar 10 is a conductor formed of a conductive metal plate and is fixed to electrodes of the battery cells 120. The busbar 10 connects, for example, two adjacent battery cells 120 in series. The flexible printed circuit board 3 connects the plurality of busbars 10 to a monitoring device 130 of the battery pack 100. The flexible printed circuit board 3 may connect a thermistor disposed in the battery cell 120 to the monitoring device 130. The monitoring device 130 is a device that monitors a state such as a voltage or a temperature of the battery cell 120.

The monitoring device 130 according to the present embodiment manages the battery cells 120 included in the battery module 110 by dividing the battery cells 120 into a plurality of cell groups. The plurality of cell groups include a first cell group G1 and a second cell group G2. The first cell group G1 and the second cell group G2 each include a plurality of battery cells 120 arranged continuously. The first cell group G1 and the second cell group G2 are adjacent to each other.

The monitoring device 130 includes an arithmetic circuit 140 that monitors the plurality of cell groups. The arithmetic circuit 140 is, for example, an integrated circuit (IC). The arithmetic circuit 140 monitors the battery cells 120 of the first cell group G1 and the battery cells 120 of the second cell group G2.

The flexible printed circuit board 3 is connected to the monitoring device 130 via a connector 5. The flexible printed circuit board 3 includes a plurality of detection lines 9. Each detection line 9 is a circuit pattern formed of a conductive metal. The detection line 9 is connected to the arithmetic circuit 140 via the connector 5 and a circuit of the monitoring device 130.

The detection line 9 is connected to a corresponding busbar 10 via the chip fuse 6 mounted on the flexible printed circuit board 3. At least one detection line 9 is connected to one busbar 10. The busbars 10 corresponding to the first cell group G1 include busbars 10a and 10b positioned at end portions in the arrangement direction AR. The busbar 10a positioned at one end portion is a busbar 10 connected to one battery cell 120a positioned at an end portion of the battery module 110. The busbar 10a is connected to, for example, an electrode on the lowest potential side in the battery module 110, a so-called total negative electrode.

One detection line 91 is connected to the busbar 10a. The detection line 91 is connected to the arithmetic circuit 140 as, for example, a GND line. The detection line 91 may be used as a line for voltage detection.

The busbar 10b is a busbar 10 positioned at an end portion that is opposite to the end portion at which the busbar 10a is positioned among the plurality of busbars 10 corresponding to the first cell group G1. That is, the busbar 10b is connected to an electrode on the highest potential side in the first cell group G1.

The plurality of detection lines 9 include two detection lines 93 and 94 connected to the busbar 10b. Each of the two detection lines 93 and 94 is connected to the arithmetic circuit 140. Among the two detection lines 93 and 94, one detection line 93 is a line for voltage detection of the busbar 10b. Among the two detection lines 93 and 94, the other detection line 94 is a line serving as a total positive electrode of the first cell group G1. The arithmetic circuit 140 monitors the battery cells 120 of the first cell group G1 based on detection results of the detection lines 9 including the detection lines 91, 93, and 94.

The busbars 10 of the second cell group G2 are further connected to the arithmetic circuit 140 via the detection lines 9. The arithmetic circuit 140 monitors the battery cells 120 of the second cell group G2 based on detection results of the detection lines 9 connected to the busbars 10 of the second cell group G2.

As described above, the busbar module 1 according to the present embodiment is configured such that the battery cells 120 of the plurality of cell groups including the first cell group G1 and the second cell group G2 can be monitored by the arithmetic circuit 140.

As illustrated in FIGS. 1 and 2, the flexible printed circuit board 3 includes a main line portion 30 and a plurality of branch portions 31. The flexible printed circuit board 3 includes a base film, a coverlay, and a conductive layer. The base film and the coverlay are flexible insulating resin layers. The conductive layer is sandwiched between and protected by the base film and the coverlay. The conductive layer is, for example, a conductive metal foil, and includes a plurality of circuit patterns.

The main line portion 30 has a longitudinal direction X and a width direction Y. The width direction Y is orthogonal to the longitudinal direction X. The plurality of detection lines 9 extend in the main line portion 30. The branch portion 31 branches from an edge of the main line portion 30 in the width direction Y. The branch portion 31 according to the present embodiment extends in the width direction Y from the main line portion 30.

As illustrated in FIGS. 2 and 4, the flexible printed circuit board 3 includes a branch portion 31b corresponding to the busbar 10b. The flexible printed circuit board 3 is provided with a mounting region 33 in which the plurality of chip fuses 6 are mounted. The mounting region 33 is disposed at a branch point 30b where the branch portion 31b branches from the main line portion 30.

Two sets of contact portions 34 corresponding to the detection lines 93 and 94 are disposed in the mounting region 33. One set of contact portions 34 includes a contact 34a connected to the detection line 9 and a contact 34b connected to a connection line 35. Each chip fuse 6 is mounted so as to be interposed between the set of contacts 34a and 34b. One connection line 35 extends on the branch portion 31b and connects the two sets of contact portions 34 and the busbar 10b.

A connection portion 32 at which a conductive plate 11 is disposed is provided at a distal end of each branch portion 31. A set of pads 32a connected to the plate is exposed at the connection portion 32. The connection line 35 of the branch portion 31b is connected to the pad 32a. A plurality of pads 30a for connection of the reinforcing plate 7 are exposed in the vicinity of the mounting region 33.

As illustrated in FIG. 2, the reinforcing plate 7 having a frame shape surrounding the mounting region 33 is disposed on the main line portion 30. The reinforcing plate 7 according to the present embodiment has a rectangular frame shape. The reinforcing plate 7 is made of metal, for example. In this case, the reinforcing plate 7 is fixed to the pads 30a with solders or the like. The reinforcing plate 7 may be made of a resin or the like. In this case, the reinforcing plate 7 may be fixed to the flexible printed circuit board 3 by adhesion or the like. Two of the chip fuses 6 and the mounting region 33 are housed in a space portion 70 surrounded by the reinforcing plate 7.

The conductive plate 11 is fixed to the connection portion 32 of the branch portion 31b. The plate 11 is fixed to the set of pads 32a with solders or the like. Further, the plate 11 is electrically connected to the busbar 10b. Therefore, the connection line 35 is connected to the busbar 10b via the plate 11.

FIG. 5 illustrates a cross section taken along line V-V of FIG. 2. As illustrated in FIG. 5, two of the chip fuses 6 are housed in the space portion 70 surrounded by the reinforcing plate 7. The potting agent 8 fills the space portion 70 to cover the two chip fuses 6 and the mounting region 33. In the busbar module 1 according to the present embodiment, the plurality of chip fuses 6 are mounted in one mounting region 33, and the potting agent 8 covers the plurality of chip fuses 6 disposed in one mounting region 33. Therefore, the busbar module 1 according to the present embodiment can achieve size reduction of the mounting region and cost reduction by the integration of the chip fuses 6.

In a case where one detection line 9 is connected to one busbar 10, the chip fuse 6 is mounted at the distal end of the branch portion 31. As illustrated in FIG. 1, the plurality of busbars 10 include a busbar 10 connected to one detection line 9. The detection line 9 for the busbar 10 is connected to the plate 11 from the main line portion 30 via the branch portion 31. The chip fuse 6 is mounted in a region surrounded by the frame-shaped plate 11. The detection line 9 is connected to the busbar 10 via the chip fuse 6 and the plate 11.

FIG. 6 illustrates a case member 4E included in the case 4. The case 4 according to the present embodiment is formed by connecting a plurality of case members 4E to each other. That is, the case 4 according to the present embodiment is configured to be expandable by connecting the plurality of case members 4E. It is possible to easily support the long flexible printed circuit board 3 by connecting the plurality of case members 4E.

The case member 4E includes a main body 40 including a routing path 41, and a cover 42 covering the routing path 41. In the case member 4E according to the present embodiment, the main body 40 and the cover 42 are integrally molded. However, the main body 40 and the cover 42 may be different members.

The main body 40 according to the present embodiment has a substantially rectangular shape in plan view. The main body 40 includes the routing path 41 and a plurality of holding portions 43. The routing path 41 is a groove-shaped path for housing the flexible printed circuit board 3. The routing path 41 includes a support wall 41a that supports the main line portion 30 of the flexible printed circuit board 3. The routing path 41 extends from one end to the other end of the main body 40 in a longitudinal direction.

The holding portion 43 is a portion that houses and holds the busbar 10. The plurality of holding portions 43 are adjacent to the routing path 41 in a width direction of the main body 40 and are arranged along the routing path 41. The holding portion 43 is formed in a frame shape and includes a locking portion that locks the busbar 10. The branch portion 31 of the flexible printed circuit board 3 extends between two adjacent holding portions 43.

The cover 42 is connected to the main body 40 via a hinge portion 46. The cover 42 includes a trunk portion 42a covering the main line portion 30 of the flexible printed circuit board 3 and a branch portion 42b covering the branch portion 31. The cover 42 includes a plurality of branch portions 42b. The branch portion 42b protrudes from the trunk portion 42a in the width direction. An engagement portion 42e that is engaged with the main body 40 is provided at a distal end of the branch portion 42b.

Engagement portions 44 and 45 that are engageable with each other are provided at both ends of the case member 4E in a longitudinal direction. Two case members 4E are connected by engaging the engagement portion 44 of one case member 4E with the engagement portion 45 of the other case member 4E. The case member 4E may include a clip or the like that is engaged with the battery module 110.

The plurality of chip fuses 6 mounted in the mounting region 33 may be connected to different busbars 10, respectively. FIG. 7 illustrates another busbar module 1 according to the embodiment. A main line portion 30 of a flexible printed circuit board 3 is provided with a mounting region 33. The mounting region 33 is disposed, for example, between two adjacent branch portions 31c and 31d. The two branch portions 31c and 31d are connected to different busbars 10, respectively. One branch portion 31c is connected to one busbar 10c of two adjacent busbars 10c and 10d. The other branch portion 31d is connected to the other busbar 10d of the two busbars 10c and 10d. Two chip fuses 6 are mounted in the mounting region 33.

One chip fuse 6 is connected to one busbar 10c. The busbar 10c is connected to the arithmetic circuit 140 of the monitoring device 130 via the chip fuse 6 and a detection line 95. The other chip fuse 6 is connected to the other busbar 10d. The busbar 10d is connected to the arithmetic circuit 140 via the chip fuse 6 and a detection line 96. A reinforcing plate 7 surrounding the mounting region 33 corresponding to the busbars 10c and 10d is fixed to the flexible printed circuit board 3. A space portion surrounded by the reinforcing plate 7 is filled with a potting agent 8 covering the two chip fuses 6.

As described above, the busbar module 1 according to the present embodiment includes the flexible printed circuit board 3, the plurality of busbars 10 connected to the flexible printed circuit board 3, the plurality of chip fuses 6 connected to the busbars 10, and the potting agent 8 covering the plurality of chip fuses 6. The plurality of chip fuses 6 are mounted in one mounting region 33 of the flexible printed circuit board 3. The potting agent 8 is disposed in one mounting region 33 and covers the plurality of chip fuses 6. With the busbar module 1 according to the present embodiment, it is possible to improve manufacturing efficiency and achieve cost reduction by integrating the plurality of chip fuses 6.

The busbar module 1 according to the present embodiment includes the reinforcing plate 7 having a frame shape surrounding one mounting region 33. The potting agent 8 fills the space portion surrounded by the reinforcing plate 7. As the plurality of chip fuses 6 are surrounded by one reinforcing plate 7, it is possible to improve the manufacturing efficiency and achieve cost reduction.

The flexible printed circuit board 3 according to the present embodiment includes the main line portion 30 and the branch portion 31 branching from the main line portion 30 and connected to the busbar 10. One mounting region 33 is disposed, for example, at the branch point 30b where the branch portion 31 branches from the main line portion 30. As the mounting region 33 is disposed at the main line portion 30, it is easy to secure the mounting region 33 having an appropriate size according to the number of chip fuses 6 to be mounted.

The plurality of chip fuses 6 may be connected to one busbar 10 via one connection line 35 disposed on the branch portion 31. With such a configuration, it is possible to connect the plurality of chip fuses 6 to the busbar 10 without changing a dimension of the branch portion 31.

The flexible printed circuit board 3 includes, for example, the main line portion 30 and the plurality of branch portions 31 branching from the main line portion 30 and connected to the busbar 10. One mounting region 33 is disposed at, for example, the main line portion 30. As illustrated in FIG. 7, the plurality of chip fuses 6 mounted in one mounting region 33 may be connected to different busbars 10, respectively. With such a configuration, it is possible to improve the manufacturing efficiency and achieve cost reduction by integrating the plurality of chip fuses 6.

The busbar module 1 does not have to include the reinforcing plate 7 surrounding the mounting region 33. In this case, the potting agent 8 is applied so as to cover the plurality of chip fuses 6 and the mounting region 33. The potting agent 8 may be a curable resin or may be formed of a plurality of layers of different materials.

The number of chip fuses 6 mounted in one mounting region 33 is not limited to the number exemplified in the present embodiment. For example, three or more chip fuses 6 may be mounted in one mounting region 33. The plurality of chip fuses 6 disposed in one mounting region 33 may be connected to one busbar 10 or may be connected to a plurality of different busbars 10. The number of mounting regions 33 provided in one flexible printed circuit board 3 is not limited to the number exemplified in the present embodiment.

The contents disclosed in the above embodiment can be appropriately combined and executed.

In the busbar module according to the present embodiment, the plurality of chip fuses are mounted in one mounting region of the flexible printed circuit board, and the potting agent is disposed in one mounting region to cover the plurality of chip fuses. With the busbar module according to the present embodiment, it is possible to improve manufacturing efficiency by integrating a plurality of chip fuses in one mounting region.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A busbar module comprising:
a flexible printed circuit board;
a plurality of busbars connected to the flexible printed circuit board;
a plurality of chip fuses connected to the busbar; and
a potting agent covering the plurality of chip fuses, wherein
the plurality of chip fuses are mounted in one mounting region of the flexible printed board, and
the potting agent is disposed in the one mounting region and covers the plurality of chip fuses.

2. The busbar module according to claim 1, further comprising:
a reinforcing plate having a frame shape surrounding the one mounting region, wherein
the potting agent fills a space portion surrounded by the reinforcing plate.

3. The busbar module according to claim 1, wherein
the flexible printed circuit board includes a main line portion and a branch portion that branches from the main line portion and is connected to the busbar, and
the one mounting region is disposed at a branch point where the branch portion branches from the main line portion.

4. The busbar module according to claim 3, wherein
the plurality of chip fuses are connected to one of the busbars via one connection line disposed on the branch portion.

5. The busbar module according to claim 1, wherein
the flexible printed circuit board includes a main line portion and a plurality of branch portions that branch from the main line portion and are connected to the busbars,
the one mounting region is disposed at the main line portion, and
the plurality of chip fuses mounted in the one mounting region are connected to the different busbars.
